(19) United States
(12) Patent Application Publication
(10) Pub. No.: US 2014/0103929 A1
(43) Pub. Date: Apr. 17, 2014

(54) SYSTEMS AND METHODS FOR SUSCEPTIBILITY TENSOR IMAGING IN THE P-SPACE

(71) Applicant: Chunlei Liu, Chapel Hill, NC (US)

(72) Inventor: Chunlei Liu, Chapel Hill, NC (US)

(21) Appl. No.: 14/051,650

(22) Filed: Oct. 11, 2013

Related U.S. Application Data
(60) Provisional application No. 61/713,522, filed on Oct. 13, 2012.

(51) Int. Cl. G01R 33/561

(52) U.S. Cl. CPC G01R 33/561
USPC 324/309

(57) ABSTRACT

Systems and methods for susceptibility tensor imaging in the p-space are disclosed. An example method includes using an MRI system to generate an MRI signal of an object. The method may also include conducting a multipole analysis of the MRI signal in a subvoxel Fourier spectral space (p-space). Further, the method may include sampling the p-space with pulsed field gradients to determine a set of dipole and quadrupole susceptibility tensors. The method may also include generating an image of the object based on the set of dipole and quadrupole susceptibility tensors for depicting a characteristic of the object.

### CROSS REFERENCE TO RELATED APPLICATION

This application claims the benefit of U.S. provisional patent application Ser. No. 61/713,522, filed Oct. 13, 2012, the disclosure of which is incorporated herein by reference in its entirety.

### TECHNICAL FIELD

The presently disclosed subject matter relates to imaging. Particularly, the presently disclosed subject matter relates to systems and methods for susceptibility tensor imaging in the p-space.

### BACKGROUND

Measuring frequency shift is fundamental to nuclear magnetic resonance (NMR) spectroscopy for probing molecular structure. Magnetic resonance imaging (MRI), on the other hand, has relied on the amplitude of the NMR signal from the very beginning to generate tissue contrast. While high-resolution NMR techniques provide a wealth of information, adapting those techniques to in vivo imaging is not yet possible. The difficulty is partially due to the low sensitivity, the limited scan time and the vastly more complex physiological condition encountered in human imaging. Because of these difficulties, frequency shift measured by MRI has been limited to the zero-th order information, i.e. the mean frequency of a whole voxel. Higher-order information such as susceptibility anisotropy of dipoles and quadrupoles, if resolved, can provide important information of sub-voxel tissue and cellular architecture. Similar to the revolutionary role that NMR has played in untangling molecular structure, imaging higher order frequency variation can provide a powerful tool for probing tissue microstructure, such as brain connectivity, in vivo and noninvasively.

The backbone of brain connectivity is composed of bundled long projecting axons. Structurally, this connectivity backbone may be compared to the backbones of macromolecules such as the double helix of the DNA. While the molecular backbone results in an NMR measurable anisotropic susceptibility tensor, recent MRI studies revealed that axon bundles also produce anisotropic susceptibility. While the mean susceptibility of a voxel can be imaged with a gradient echo, it does not measure the orientation dependence of the susceptibility. To measure the anisotropy of magnetic susceptibility, the method of susceptibility tensor imaging (STI) has been used. A recent study also explored the capability of STI for tracking neuronal fibers in 3D in the mouse brain ex vivo. In large fiber bundles, the orientation determined by STI was found to be comparable to that by diffusion tensor imaging (DTI). However, the experimental setup of STI requires rotation of the object or the magnetic field. This requirement is clearly inconvenient for routine brain imaging on standard MRI scanners in vivo.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

In accordance with embodiments of the present disclosure, systems and methods measure higher-order frequency variations based on a single image acquisition without rotating the object or the magnet. An example method utilizes a multipole analysis of the MRI signal in a subvoxel Fourier spectral space termed “p-space” for short. By sampling the p-space with pulsed field gradients, the method is capable of measuring a set of dipole and quadrupole susceptibility tensors and so on. An example method is illustrated in a simulation of aligned axons and demonstrated its use for 3D high resolution white matter imaging of mouse brains ex vivo at 9.4 Tesla and human brains in vivo at 3.0 Tesla. It has been further demonstrated how the skeletons of the spiny neurons in the mouse striatum can be reconstructed. The method can be used to characterize materials microstructures including for example biological tissues, porous media, oil sands and rocks. This method may be used to aid oil and gas exploration and to aid the study and design of fuel cells.

Disclosed herein are systems and methods for imaging and quantifying microscopic electromagnetic field distribution, microstructural orientations and connectivity of materials such as, but not limited to, biological organs (e.g., the brain). A method can provide internal electromagnetic field and structural connectivity of materials and organs that cannot be visualized otherwise. A set of magnetic susceptibility tensors are defined. Steps are outlined to measure these quantities using MRI. The method is demonstrated with simulation and MRI experimentations of brains ex vivo and in vivo on a standard 3T MRI scanner. An important innovation of a method disclosed herein is that it utilizes a single image acquisition and does not require rotation of the object or the magnetic field. The method is applicable for disease detection in medical diagnosis, treatment planning and monitoring, and electromagnetic field induced by bioelectricity such as neuronal activity. In non-medical applications, the method can also be used to aid oil and gas exploration.

According to an aspect, a method for susceptibility tensor imaging in the p-space is disclosed. The method may include using an MRI system to generate an MRI signal of an object. The method may also include measuring subvoxel electromagnetic fields in a spectral space (p-space).

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The foregoing summary, as well as the following detailed description of various embodiments, is better understood when read in conjunction with the appended drawings. For the purposes of illustration, there is shown in the drawings exemplary embodiments; however, the presently disclosed subject matter is not limited to the specific methods and instrumentalities disclosed. In the drawings:

FIG. 1 is a block diagram of an MRI system in accordance with embodiments of the present disclosure.

FIG. 2 depicts a flowchart of an example method for constructing the p-space in accordance with embodiments of the present disclosure. Particularly, FIG. 2(a) Pulse sequence for sampling the p-space which can be achieved by applying pulsed field gradients or by shifting k-space data. FIG. 2(b) Basic steps of analyzing p-space signal. At each location in the p-space, a complex image is reconstructed by inverse Fast Fourier Transform (IFFT). The magnitude and phase images are normalized by those at p=0.

FIG. 3 depicts various images and graphs of example p-space analysis of a simulated bundle of axons in accordance with embodiments of the present disclosure. Particularly, FIG. 3(a) shows a schematic representation of the axonal bundle and the frequency distribution in the axial plane. Two scenarios were evaluated: one without noise (b-d) and the other with SNR=20 (e-g). FIG. 3(b) shows a magnitude profile along five p-space orientations showing small orientation variations. FIG. 3(c) shows a frequency profile along the same five orientations showing significant orientation variations. FIG. 3(d) shows a surface rendering (glyph) of the standard deviation of magnitude and phase. The glyphs based on frequency clearly illustrated the orientation of the axons. Similar results were found for SNR=20.

FIG. 4 depicts various graphs and images of p-space signal behavior of a mouse brain. Particularly, FIG. 4(a) shows a representative magnitude image at p=0. FIG. 4(b) shows three normalized magnitude images at p=−0.45, −0.25 and 0.45 respectively along y-axis (left-right). FIG. 4(c) shows corresponding phase image at p=0. FIG. 4(d) shows corresponding normalized frequency images at p=−0.45, −0.25 and 0.45 respectively. FIG. 4(e) shows normalized magnitude as a function of the p-value in corpus callosum (CC), hippocampal commissure (HC) and gray matter. The voxel locations were shown in FIG. 4(a). FIG. 4(f) shows normalized frequency as a function of the p-value in the same three voxels. While little p-value dependence was observed in the gray matter, significant dependence was evident in the white matter.

FIG. 5 shows example images computed from dipole frequency and quadrupole magnitude in accordance with embodiments of the present disclosure. Particularly, FIG. 5(a) shows standard deviations of the dipole frequency along three orthogonal p-space orientations: [1 0 0], [0 1 0] and [0 0 1]. The contrast within the white matter showed visible orientation dependence. gcc—genu of corpus callosum; hc—hippocampus; acp—posterior portion of anterior commissure. FIG. 5(b) shows eigenvalues of the diapole susceptibility tensor computed from the frequency. Anisotropy was evident from the differences in the eigenvalues and elongated glyphs in the gcc, hc and acp. FIG. 5(c) shows standard deviations of the quadrupole magnitude did not show significant orientation variations among the three directions. FIG. 5(d) shows eigenvalues of the quadrupole susceptibility tensor computed from the magnitude did not show significant differences. However, they provided high contrast between gray and white matter.

FIG. 6 shows examples of images computed from quadrupole frequency and dipole magnitude. Particularly, FIG. 6(a) shows standard deviations of quadrupole frequency and dipole magnitude along three orthogonal p-space orientations ([1 0 0], [0 1 0] and [0 0 1]) and the mean standard deviations of all directions. Both frequency and magnitude showed significant orientation variations. FIG. 6(b) shows fractional anisotropy (FA) and color-coded minor eigenvector of all four tensors. Only the quadrupole susceptibility tensor of the magnitude (η_{q}) had low FA and exhibited different minor-eigenvector orientations.

FIG. 7 depicts images shows example eigenvector orientation and ultra-resolution fiber tractography. Particularly, FIG. 7(a) shows color-coded minor eigenvector of dipole susceptibility tensor computed from frequency. Orientations of major fiber tracts can be identified. gcc—genu of corpus callosum; ic—internal capsule; hc—hippocampus; csc—commissure of superior colliculus; ac—anterior commissure; tt—trigeminal tract. FIG. 7(b) shows maximum intensity projection (MIP) of the trace of the quadrupole susceptility tensor in the striatum along dorsal-ventral direction. Scale bar=300 μm. FIG. 7(c) shows an coronal section of the quadrupole tensor trace. FIG. 7(d) shows an AChE staining section at approximately the same location as in FIG. 7(c). FIG. 7(e) shows a reconstructed 3D spiny neuron projections in the striatum. An example of interneuron was indicated by arrows.

FIG. 8 shows various images and graphs of p-space signal behavior of a human brain in accordance with embodiments of the present disclosure. Particularly, FIG. 8(a) shows a representative magnitude image at p=0. FIG. 8(b) shows three normalized magnitude images at p=−0.45, −0.25 and 0.45 respectively along y-axis (left-right). FIG. 8(c) shows corresponding phase image at p=0. FIG. 8(d) shows corresponding normalized frequency images at p=−0.45, −0.25 and 0.45 respectively. FIG. 8(e) shows normalized magnitude as a function of the p-value in genu of corpus callosum (GCC), optical radiation (OR) and gray matter (GM). The voxel locations were shown in FIG. 8(a). FIG. 8(f) shows normalized frequency as a function of the p-value in the same three voxels. While little p-value dependence was observed in the gray matter, significant dependence was evident in the white matter.

FIG. 9 depicts images of p-space tensor reconstruction of human brain in vivo. Particularly, FIG. 9(a) shows inverse standard deviations of the dipole magnitude and frequency along three orthogonal orientations. White matter contrast is clearly orientation dependent (pcr—posterior corona radiata; scc—splenium of the corpus callosum). FIG. 9(b) shows inverse trace of the dipole susceptibility tensor χ_{d} and color-coded minor eigenvectors in the axial, coronal and sagittal planes. FIG. 9(c) shows inverse standard deviations of the quadrupole magnitude and frequency along three orthogonal orientations. White matter contrast is orientation dependent for the quadrupole frequency but not for the quadrupole magnitude. FIG. 9(d) shows inverse trace of the quadrupole susceptibility tensor χ_{q} and color-coded minor eigenvectors in the axial, coronal and sagittal planes.

FIG. 10 shows images of p-space tensor reconstruction of human brain in vivo. Particularly, FIG. 10(a) shows standard deviations of the dipole magnitude and frequency along three orthogonal orientations. FIG. 10(b) FA of the dipole susceptibility tensor η_{d} and color-coded minor eigenvectors in the axial, coronal and sagittal planes. FIG. 10(c) shows standard deviations of the quadrupole magnitude and frequency along three orthogonal orientations. White matter contrast is highly orientation dependent for the quadrupole frequency but less so for the quadrupole magnitude. FIG. 10(d) shows FA of the quadrupole susceptibility tensor η_{q} and color-coded minor eigenvectors in the axial, coronal and sagittal planes.

FIG. 11 is a schematic representation of the different regions in the FOV: I and O are interior and boundary regions of the object, respectively, and E is the exterior of the object.

FIG. 12 depicts images of numerical simulations using a Shepp-Logan phantom. Images A and B show the phantom in two orthogonal views. Images C and D show images of a simulated phase with the external susceptibility source. Images E and F show images of simulated phase without the external susceptibility source. Images G and H show images of background removed phase using HARPERELLA. Images I and J show images depicting the difference between the background-removed phase (G, H) and the phase generated by the phantom in the absence of the external susceptibility source (E, F).

FIG. 13 show images depicting a HARPERELLA phase processing. Images A shows original tissue phase. Image B shows an image of a Laplacian of the raw phase. Image C shows an image of a Laplacian of the raw phase inside the brain. Image D shows an image of a Laplacian of the phase throughout the FOV computed using HARPERELLA. It is noted that the Laplacian outside the brain is non-zero in D. Images E and F show images of the spherical mean value filtered images of C and D, respectively. Images G and H show images of the unwrapped phase calculated from E and F using the FFT-based inverse Laplacian.

FIG. 14 shows tissue phase images obtained using HARPERELLA in vivo from a human brain.

FIG. 15 show images of an example showing the robustness of the Laplacian-based phase unwrapping. Image A shows magnitude. Image B shows raw phase. Image C shows unwrapped phase using the Laplacian-based phase unwrapping followed by a simple high-pass filtering. The Laplacian-based phase unwrapping can yield a continuous phase map of the blood vessel, which is surrounded by excessive amount of noise and phase wraps.

### DETAILED DESCRIPTION

The presently disclosed subject matter is described with specificity to meet statutory requirements. However, the description itself is not intended to limit the scope of this patent. Rather, the inventors have contemplated that the claimed subject matter might also be embodied in other ways, to include different steps or elements similar to the ones described in this document, in conjunction with other present or future technologies. Moreover, although the term “step” may be used herein to connote different aspects of methods employed, the term should not be interpreted as implying any particular order among or between various steps herein disclosed unless and except when the order of individual steps is explicitly described.

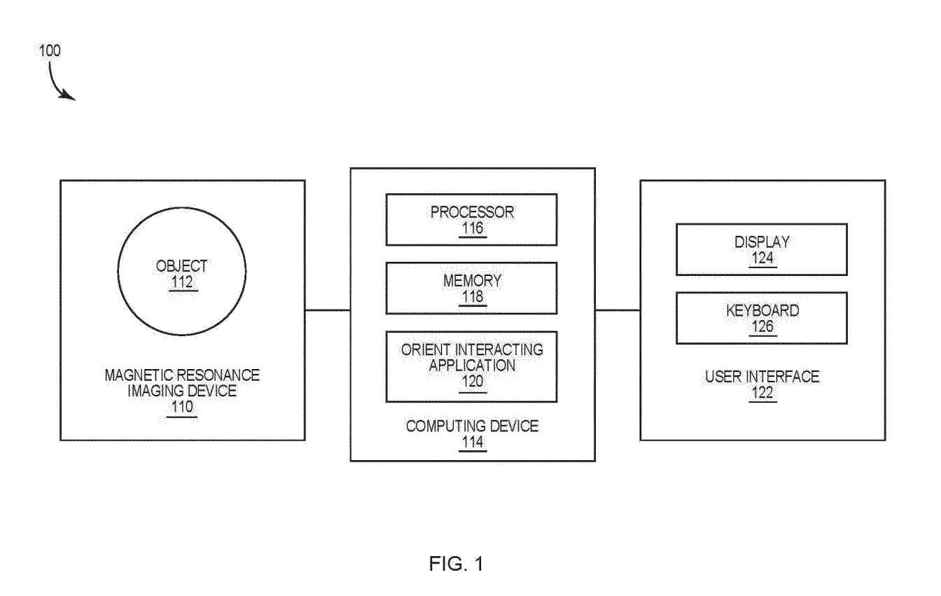

FIG. 1 illustrates a block diagram of a magnetic resonance imaging (MRI) system 100 in accordance with embodiments of the present disclosure. Referring to FIG. 1, the system 100 may include an MRI device 110. The MRI device 110 may be configured for scanning and capturing an image of an object 112 such as an anatomical image of an object. Example objects to be imaged include, but are not limited to, brain tissue, kidney tissue, liver tissue, heart tissue, and any other bodily tissues. The MRI system 100 may include a computing device 114. The computing device 114 may include a processor 116, a memory 118, and an object interacting application 120 that is configured to execute on the processor 116. The MRI system 110 may include a user-interface 122, such as an image generator, that is configured to display images on a display 124 and to receive user input through a user input device, such as, for example, a keyboard 126.

### Example Methods

The Spectral Space (p-Space) of Microscopic Magnetic Field

For a given imaging voxel containing heterogeneous structures, the magnetic field within the voxel is also heterogeneous. The total magnetization of the voxel is an integral of all spins within the voxel, each experiencing a different local field depending on its location. The phase angle of the resulting integral represents the amplitude of the mean field. The spatial heterogeneity, however, is lost during the ensemble averaging. If the field distribution within the voxel can be recovered, the underlying tissue microstructure may be inferred.

To probe the sub-voxel field pattern, an external magnetic field gradient can be applied. This external gradient field modulates the resonance frequency of the spins within the voxel. Specifically, given a voxel of width [v₁, v₂, v₃] centered at location r in the laboratory's frame of reference, the field within the voxel can be denoted as B(r+x). Here, x is the coordinate of a spin in the voxel's frame of reference whose origin is at the center of the voxel. Both r and x are normalized by the width of the voxel. In the presence of a pulsed field-gradient G, the voxel-averaged MRI signal s(r) at time t is given by:

$$s ( r ) = {\int }_{x} ρ ( r x ) {e}^{- iγ ( {B}_{3} ( r + x ) + G \cdot ( r + x ) ) t} d x \qquad [ 1 ]$$

Here, B₃(r+x) is the z-component of B(r+x) which is along the direction of the B₀ field; ρ(r) is the spin density at position r and γ is the gyromagnetic ratio. Eq. [1] can be rewritten as:

$$s ( r ) = {e}^{- i 2 π p \cdot r} {\int }_{x} ρ ( x ) {e}^{- iγ {B}_{3} ( x ) t} {e}^{- i2π p \cdot x} d x \qquad [ 2 ]$$

where p is a normalize spatial frequency vector with pᵢ=γGᵢvᵢt/2π. The symbol r has been dropped in the integral with the understanding that both ρ and B₃ are expressed in the voxel's coordinate system. Recognizing the Fourier Transform (FT) relationship, Eq. [2] can be further written as:

s(r,p)=e^{-i2πp·r} FT {ρ(x)e^{-iγB}^{₃}^{(x)t}} [3]

In other words, the magnetization is proportional to the spectrum of the complex magnetization distribution function. Herein, this spectral space will be referred to as the “p-space” to differentiate it from the k-space that is commonly used in image acquisition. The Fourier term in Eq. [3] can be split into magnitude m(r, p) and phase Φ(r,p) as follows:

FT {ρ(x)e^{-iγB}^{₃}^{(x)t}}=m(r,p)e^{-iΦ(r,p)} [4]

Both the magnitude and the phase can be expected to depend on the applied field gradient.

In a second-order multipole expansion (or Taylor's expansion in Cartesian coordinates), Φ(r,p) can be written as:

Φ(p)=Φ₀+γB₀t\hat{p}^{T}χ_{q}\hat{p}p² [5]

In Eq. [5], the first term is the mean phase. The second term is a dipole moment in which χ_{d} is a rank-2 dipole susceptibility tensor and \hat{p} is the unit directional vector. The third term is a quadrupole moment expressed in terms of a rank-2 quadrupole susceptibility tensor χ_{q}. More specifically, Φ₀ is the phase when no gradient is applied and it is related to the image-space dipole susceptibility tensor (rank 2) χ(r) following:

$${Φ}_{0} = γ t F {T}^{- 1} \{ \frac{1}{3} {\hat{B}}_{0} F T \{ χ \} {B}_{0} - {k}_{3} \frac{{k}^{T} F T \{ χ \} {B}_{0}}{{k}^{2}} \} \qquad [ 6 ]$$

Here, \hat{B}₀ is a unit directional vector (dimensionless). The quadrupole tensor χ_{q}, in its complete form, is a rank-3 tensor. However, since B₀ is in the z-direction, the third dimension of χ_{q} is fixed to index 3, thus reducing it to a rank-2 tensor.

Similarly, the magnitude can be expanded as:

m(p=m₀(1 γB₀t\hat{p}^{T}η_{d}\hat{p}p γB₀t\hat{p}^{T}η_{q}\hat{p}p²) [7]

where both η_{d} and η_{q} are dimensionless rank-2 tensors.
Measuring p-Space Susceptibility Tensors

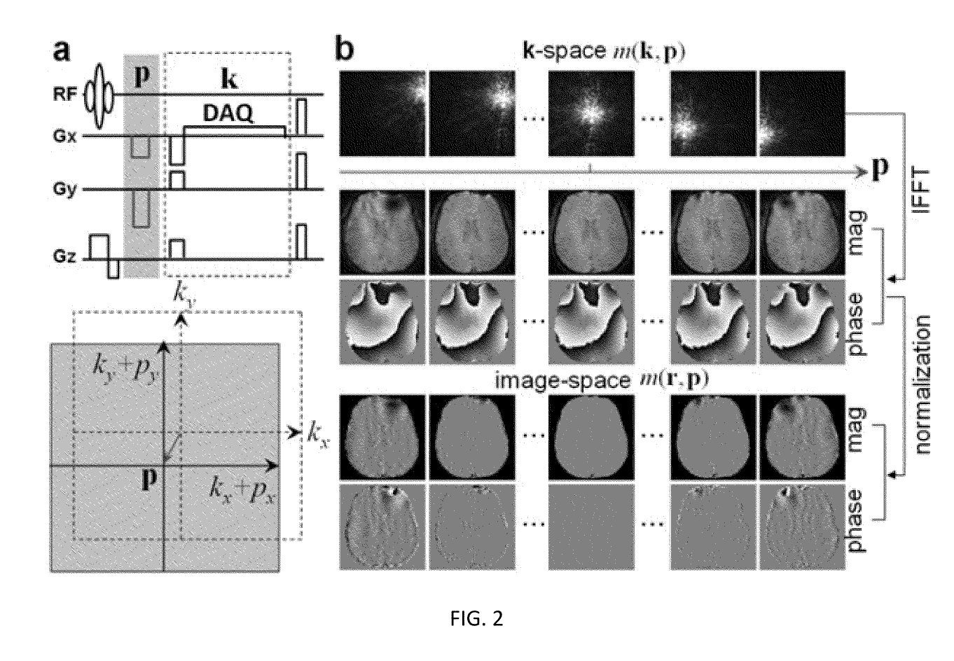

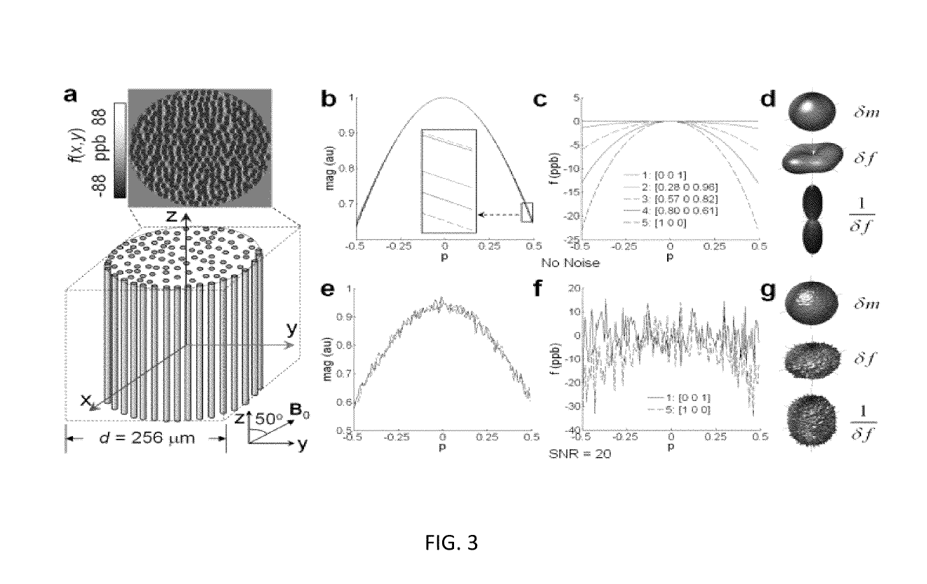

To measure these tensors, a standard gradient-echo sequence can be used with an added spectral sensitizing gradient (FIG. 3a). The spectrum-sensitizing gradient causes a shift in the k-space. Utilizing this shifting effect, spectral weighting can be achieved during image reconstruction by simply shifting the k-space data with the desired p-vector. This strategy allowed the sampling of the p-space in a uniform Cartesian grid without adding physical gradients. By shifting the reconstruction window in various directions and with various distances, a series of images can be reconstructed (FIG. 2b). For each shift in the p-space, a linear phase term is also added to the image as described in Eq. [3]. This linear phase must be removed before calculating the phase spectrum.

The p-space can be sampled in many different ways. If it is sampled on a spherical surface with a constant radius of p, the susceptibility tensors can be calculated by inverting the resulting system of linear equations defined by Eq. [5] & [8]. Alternatively, the p-space can be sampled continuously along a given direction, thus allowing the calculation of the spectral variation along that particular direction. If the maximal p-value along a unit-direction \hat{p} is denoted by pₘₐₓ, the standard deviation of the dipolar phase is given by (see details in next section):

$${δΦ}_{d} = \frac{1}{\sqrt{3}} γ {B}_{0} t {p}_{max} {\hat{p}}^{T} {χ}_{d} \hat{p} \qquad [ 8 ]$$

The standard deviation of the quadrupolar phase is given by:

$$δ {Φ}_{q} = \frac{2}{\sqrt{45}} γ {B}_{0} t {p}_{max}^{2} {\hat{p}}^{T} {χ}_{q} \hat{p} \qquad [ 9 ]$$

The standard deviations of the magnitude are given similarly with χ replaced by η. Given a set of non-colinear directions, the susceptibility tensors can be calculated by inverting Eq. [8&9]. Notice that there is a sign ambiguity when taking the square root of the variance (Supplementary Materials Note). The positive sign was chosen as a demonstration. This choice does not indicate whether the material is diamagnetic or paramagnetic as it is based on p-space moments rather than image-space susceptibility itself. A notable advantage of calculating the variance is that the absolute susceptibility tensors can be determined independent of the reference frequency.

### Deriving Standard Deviations

The mean phase of the dipolar term, Φ̅_{d}, is zero. The mean phase of the quadrupolar term along the unit-direction \hat{p} can be derived as follows:

$$\begin{matrix}{\overline{Φ}}_{q} = \frac{1}{2 {p}_{max}} {\int }_{- {p}_{max}}^{{p}_{max}} γ {B}_{0} t {\hat{p}}^{T} {χ}_{q} \hat{p} {p}^{2} d p \\ = \frac{1}{2 {p}_{max}} γ {B}_{0} t {\hat{p}}^{T} {χ}_{q} \hat{p} {\int }_{- {p}_{max}}^{{p}_{max}} {p}^{2} d p \\ = \frac{1}{3} γ {B}_{0} t {p}_{max}^{2} {\hat{p}}^{T} {χ}_{q} \hat{p}\end{matrix} \qquad [ 10 ]$$

The mean of the squared frequency is derived as:

$$\begin{matrix}\begin{matrix}\overline{{Φ}_{d}^{2}} = \frac{1}{2 {p}_{max}} {\int }_{- {p}_{max}}^{{p}_{max}} {( γ {B}_{0} t {\hat{p}}^{T} {χ}_{d} \hat{p} p )}^{2} d p \\ = \frac{1}{3} {( γ {B}_{0} t {p}_{max} {\hat{p}}^{T} {χ}_{d} \hat{p} )}^{2}\end{matrix} & [ 11 ] \\ \begin{matrix}\overline{{Φ}_{q}^{2}} = \frac{1}{2 {p}_{max}} {\int }_{- {p}_{max}}^{{p}_{max}} {( γ {B}_{0} t {\hat{p}}^{T} {χ}_{q} \hat{p} {p}^{2} )}^{2} d p \\ = \frac{1}{5} {( γ {B}_{0} t {p}_{max}^{2} {\hat{p}}^{T} {χ}_{q} \hat{p} )}^{2}\end{matrix} & [ 12 ]\end{matrix}$$

Therefore, the variances are given by:

$$\begin{matrix}{δΦ}_{d}^{2} = \overline{{Φ}_{d}^{2}} - \overline{{Φ}_{d}^{2}} = \frac{1}{3} {( γ {B}_{0} t {p}_{max} {\hat{p}}^{T} {χ}_{d} \hat{p} )}^{2} & [ 13 ] \\ {δΦ}_{q}^{2} = \overline{{Φ}_{q}^{2}} - \overline{{Φ}_{q}^{2}} = \frac{4}{45} {( γ {B}_{0} t {p}_{max}^{2} {\hat{p}}^{T} {χ}_{q} \hat{p} )}^{2} & [ 14 ]\end{matrix}$$

### Numerical Simulation

A cubic voxel packed with an ensemble of parallel axons was generated. The voxel had a dimension of d=256 μm on all sides. The axons were aligned along the z-axis. The B₀ field was parallel to the y-z plane, tilted by 50° from the z-axis (FIG. 3). The inner radius of the axon Rₐ was 3.5 μm and the outer radius Rₘ was 5.0 μm. The distance between two neighboring axons was uniformly distributed between 11.0 μm and 12.5 μm. The susceptibility of the axons was set to be −0.082 ppm and the susceptibility anisotropy (χ_{P}−χ_{⊥}) of the myelin sheath was 0.163 ppm. The susceptibility of the interstitial space was assumed to be zero as the reference. The voxel was divided into a 512×512×512 grid resulting in a grid size of 0.5-μm. A susceptibility tensor was assigned to each voxel depending on the tissue type. Only voxels within the myelin sheath had anisotropic tensors. The major eigenvectors the myelin tensors were perpendicular to the long axis of the axon. The magnetic field at each voxel was computed via the forward Fourier relationship between susceptibility tensor and magnetic field as expressed in Eq. [6]. The MR signal generated by the voxel was evaluated at TE=20 ms. A total of 10,000 unit p-vector were generated that evenly cover the surface of a unit sphere. At each orientation, the p-space was sampled in 128 evenly spaced locations in the range of [−0.5, 0.5]. Gaussian noise was added in the real and imaginary part of the signal resulting in an SNR of 20. The signal variation along a given direction was evaluated. The standard deviation was computed for both frequency and magnitude.

### MRI Experiments

Adult 10-weeks old C57BL/6 mice (n=3, The Jackson Laboratory, Bar Harbor, Me.) were anesthetized and perfusion fixed. Brains were kept within the skull to prevent potential damages caused by surgical removal. Each specimen was sealed tightly inside a cylindrical tube (length 30 mm and diameter 11 mm). The tube containing the specimen was placed inside a tightly fitted solenoid radiofrequency coil constructed from a single sheet of microwave substrate. Images were acquired on a 9.4 T (400 MHz) 89-mm vertical bore Oxford magnet with shielded coil providing gradients of 1600 mT/m. The system is controlled by a GE EXCITE MR imaging console. A 3D spoiled-gradient-recalled-echo (SPGR) sequence was used with the following parameters: matrix size=512×256×256, field-of-view (FOV)=22×11×11 mm³, bandwidth (BW)=62.5 kHz, flip angle=60°, TE=[4.4, 7.0, 9.0, 11.0, 13.0, 15.0] ms and TR=100.0 ms. Scan time was 1 hour and 49 minutes. To obtain 10-μm isotropic resolution, one brain was scanned at a matrix size of 2200×1100×1100 with TE=9.0 ms and TR=50.0 ms. To accumulate sufficient SNR, the scan was repeated 9 times and was conducted within 7 days. The study was approved by the Institutional Animal Care and Use Committee.

Three healthy adult volunteers were scanned on a 3.0 T GE MR750 scanner (GE Healthcare, Waukesha, Wis.) equipped with an 8-channel head coil and a maximal gradient strength of 50 mT/m. Images were acquired using a 16-echo 3D SPGR sequence with the following parameters: FOV=192×192×120 mm³, matrix size=192×192×120, BW=62.5 kHz, flip angle=20°, TE of the first echo=4.0 ms, echo spacing=2.3 ms and TR=50.0 ms. Total scan time was 19.2 minutes. The study was approved by the Institutional Review Board.

p-Space Data Analysis

A total of 213 orientations in the p-space were sampled. For the convenience of data shifting, these directions were expressed in signed integer numbers as [n₁ n₂ n₃] without normalization. The maximal number used was 5. To reconstruct one image, raw k-space data were first upsampled to an N×N×N matrix (N=512 for mouse and 192 for human) by zero-padding in the image domain. This operation resulted in isotropic resolution in both the k-pace and the image domain. The k-space data were then shifted to by a given p-space vector. Data shifted outside the prescribed matrix were discarded, while new locations were filled with zeros. Finally, an N×N×N image was obtained via the inverse Fourier Transform. Along each p-space orientation, N evenly spaced image volumes were reconstructed. The 15 images on either end of any direction were discarded to keep DC signal within the reconstruction window. Therefore, a total of (N-30) images were used for each orientation. If the reconstruction of an image requires non-integer shift along any dimension, the k-space data were further upsampled by zero padding along that dimension in the image domain. For example, given the direction of [1 3 1], one pixel shift in the second dimension requires a third of a pixel shift in the first and third dimension. To achieve this shift, the k-space was upsampled to a size of 3N×N×3N. For the 10-μm mouse brain, the p-space analysis was performed for the left striatum.

For each orientation, the standard deviation of the frequency and magnitude was computed. When computing the standard deviation of the frequency, the phase map at p=0 was subtracted from all images on a coil-by-coil basis. This subtraction removed both coil and background phases and did not require phase unwrapping. The resulting phase maps from all coils were then summed together. For the magnitude, images from all coils were combined via the sum of the squares and normalized by the sum-of-squares image obtained at p=0. To calculate the standard deviation of the dipole term, the frequency value at a given p-value was subtracted from that at −p and the resulting difference was derived by 2. To calculate the quadrupole term, the frequency at p was summed with that at −p and the resulting sum was divided by 2. Same procedures were applied for the magnitude. For each orientation, the pₘₐₓ value was recorded and used to compute the susceptibility tensors following Eq. [8&9]. A set of tensors were computed for each echo. Tensors from all echoes were combined to achieve optimal SNR using a weighted summation based on T₂* decay. The resulting tensors were diagnolized with eigenvalue decomposition.

### Reduction to Practice

### Simulation of Axon Bundles

The validity of the approach was verified using a simulated bundle of parallel axons that was situated in a cubic voxel (FIG. 3a). The voxel had a width of 256 μm in all sides. The susceptibility variations within the voxel created a frequency distribution in the range of ±88 parts per billion (ppb) (FIG. 3a). Assuming a magnetic field of 3.0 Tesla and an echo time (TE) of 20 ms, the signal was computed for 10,000 p-space orientations for the SPGR sequence (FIG. 2a). For each orientation, the p-gradients were varied incrementally that generated 128 p-values, evenly spaced in the range of ±0.5. Simulations were conducted without noise and with noise (SNR=20). Without noise, both magnitude and frequency showed a quadratic relationship with p as illustrated for five representative orientations (FIGS. 3(b) & 3(c)). The linear term was absent due to the cylindrical symmetry of the phantom. While the magnitude curves are very similar among all directions, the frequency curves varied significantly, demonstrating clear susceptibility anisotropy (FIG. 3(c)). Specifically, when the p-vector was parallel to the axons (direction 1: [0 0 1]), the frequency stayed constant; when the p-vector was perpendicular to the axons (direction 5: [1 0 0]), the frequency showed the largest variation. This anisotropic property was illustrated with a set of 3D color-coded glyphs (FIG. 3(d)). For each point on the surface of the glyph, the radial distance from that point to the origin was scaled by the standard deviation of the magnitude or the frequency along the corresponding radial direction. While the glyph of the magnitude appeared spherical (δm in FIG. 2d), the glyph of the frequency was donut-shaped (δf in FIG. 3(d)) with its inverse shaped like an elongated peanut (1/δf in FIG. 3(d)). From these glyphs, the orientation of the axons can be visually identified by searching for the minimum standard deviation. In the case with SNR=20, similar behaviors were observed even though significant fluctuations were present in the signal curves and the glyphs (FIGS. 3(e)-3(g)).

The quadrupole susceptibility tensor was also computed for the magnitude (denoted by η_{q}) and the frequency (denoted by χ_{q}). The dipole susceptibility tensors (η_{d} and χ_{d}) were absent as there were no linear terms in the p-space signal (FIGS. 3(b), 3(c), 3(e) & 3(f)). Note that these susceptibility tensors were defined in the p-space; they differed from their counter parts in the image space. The resulting tensors were decomposed with eigenvalue decomposition. The eigenvector corresponding to the minor eigenvalue (minor eigenvector for short) was along the z-axis for χ_{q}, the same orientation as the axons. However, for the magnitude, the minor eigenvector of η_{q} was long the y-axis. When noise was added, all eigenvalues increased. The fractional anisotropy (FA) of χ_{q} decreased from 0.727 to 0.155 while the FA of η_{q} remains relatively constant at 0.005.

p-Space STI of Mouse Brains Ex Vivo

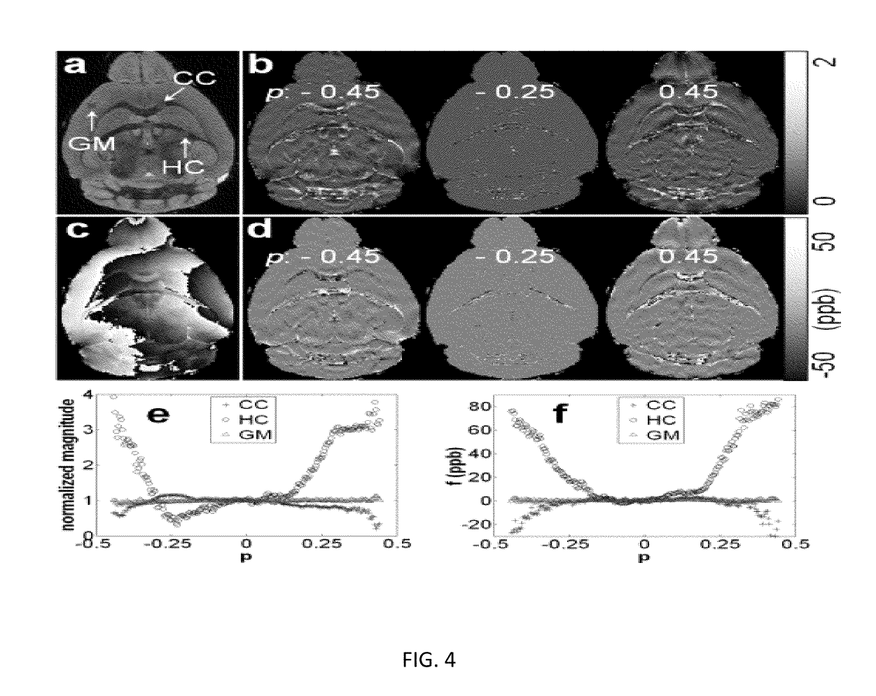

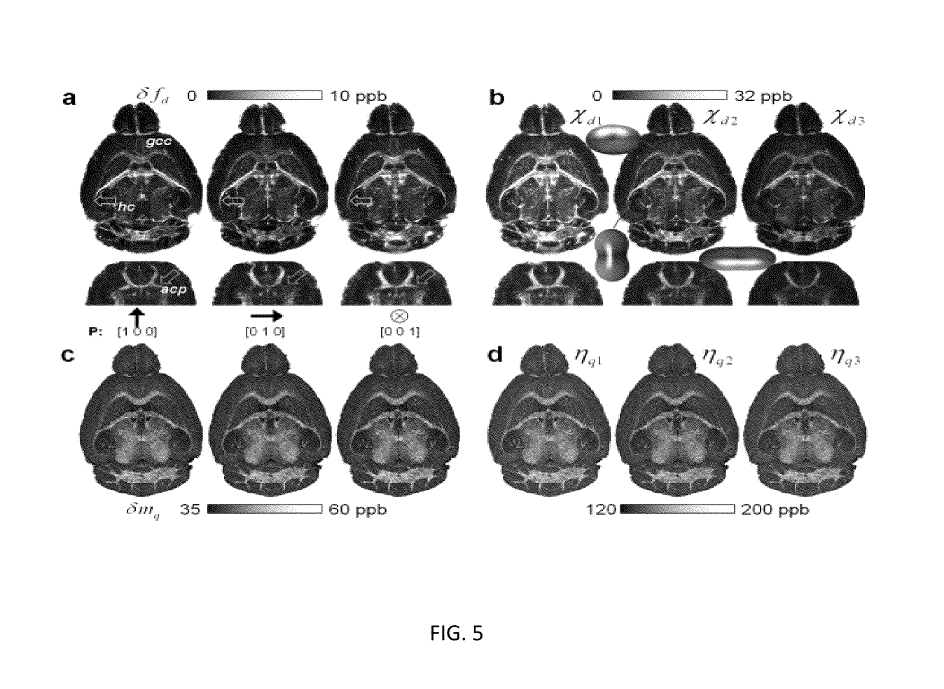

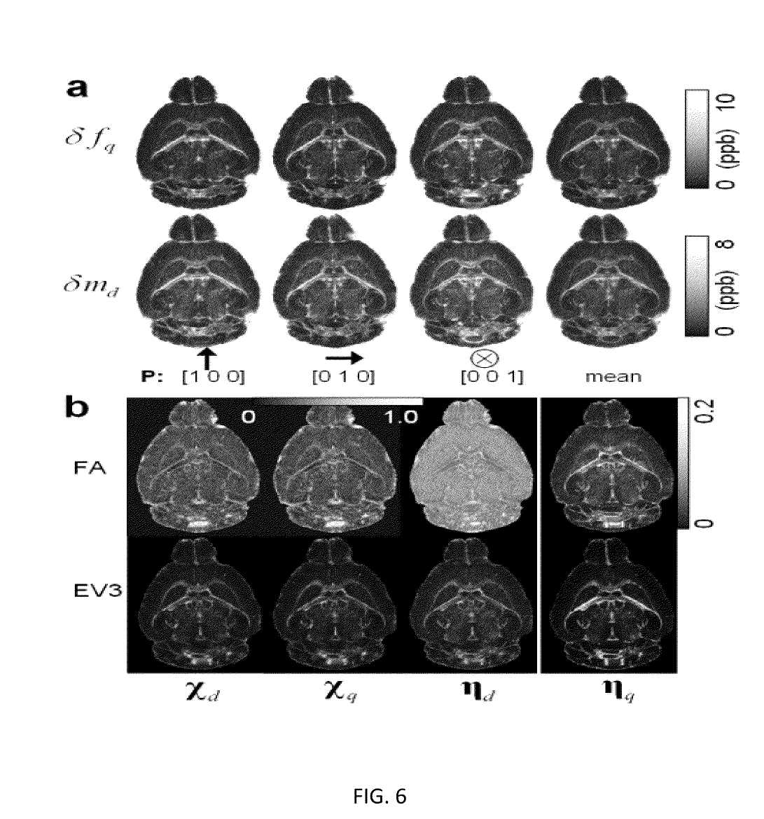

To determine whether the p-space method can measure susceptibility tensors of biological tissues, 3D SPGR images were acquired on perfusion-fixed mouse brains (C57BL/6J, n=3, 10 weeks, the Jackson Laboratory, Bar Harbor, Me.) with an isotropic resolution of 43 μm (Methods). P-space signals were generated for 213 orientations. Along any given orientation, neither the magnitude nor the frequency of the gray matter showed significant dependence on the p-value (FIG. 4). The white matter, on the other hand, demonstrated strong dependence on the p-value similar to the simulated axons. Unlike the simulation, the dependence in the mouse brains demonstrated both dipole and quadrupole relationship (FIGS. 4(e) & 4(f)). For each orientation, standard deviations were computed for the dipole and quadrupole terms for the frequency (δf_{d} for dipole and δf_{q} for quadrupole) and the magnitude (δm_{d} for dipole and δm_{q} for quadrupole). For the frequency standard deviations, both the dipole and the quadrupole term showed clear anisotropy. Specifically, when the underlying fibers were parallel to the p-vector, the dipole term δf_{d} was the smallest, e.g. in the hippocampus (hc) when p=[1 0 0] and the genu corpus callosum (gcc) and the posterior part of the anterior commissure (acp) when p=[0 1 0] (FIG. 5(a)). In particular, acp nearly vanished when p=[0 1 0] while it was the brightest when p=[0 0 1] (FIG. 5(a)). Similar behaviors were observed for the quadrupole δf_{q} (FIG. 6(a)). From the 213 standard deviations, the dipole (χ_{d}) and quadrupole (χ_{q}) susceptibility tensor were computed. The three eigenvalues of the dipole susceptibility tensor differed significantly from each other (FIG. 5(b)), confirming the anisotropy of the p-space dipole tensor. To better visualize this anisotropy, glyphs of 1/δf_{d} were generated for hc, gcc & acp (FIG. 5(b)). Similar to findings in the simulation, the long axes of the glyphs were parallel to the axon orientation. The fractional anisotropy in the white matter, though high (averaged around 0.6), did not provide good contrast between gray and white matter (FIG. 6(b)). This reduced contrast was caused by the presence of noise as demonstrated by the simulation.

For the magnitude, while the standard deviation of the dipole term (δm_{d}) exhibited similar anisotropic property as the frequency (FIG. 6(a)), the quadrupole term (δm_{q}) had low anisotropy (FIG. 5(c)). This low anisotropy was also apparent from the three comparable eigenvalues of the quadrupole susceptibility tensor (η_{d}) (FIG. 5(d)). Nevertheless, the quadrupole term provided high contrast between gray and white matter (FIGS. 4(c) & 4(d)). Although the FA of the quadrupole tensor was low (less than 0.2), it still offered high contrast between gray and white matter (FIG. 6(b)). This contrast did not appear to be affected by the noise as much as in the case of frequency, which was consistent with the findings in the simulation.

### Eigenvector Orientation and Fiber Reconstruction

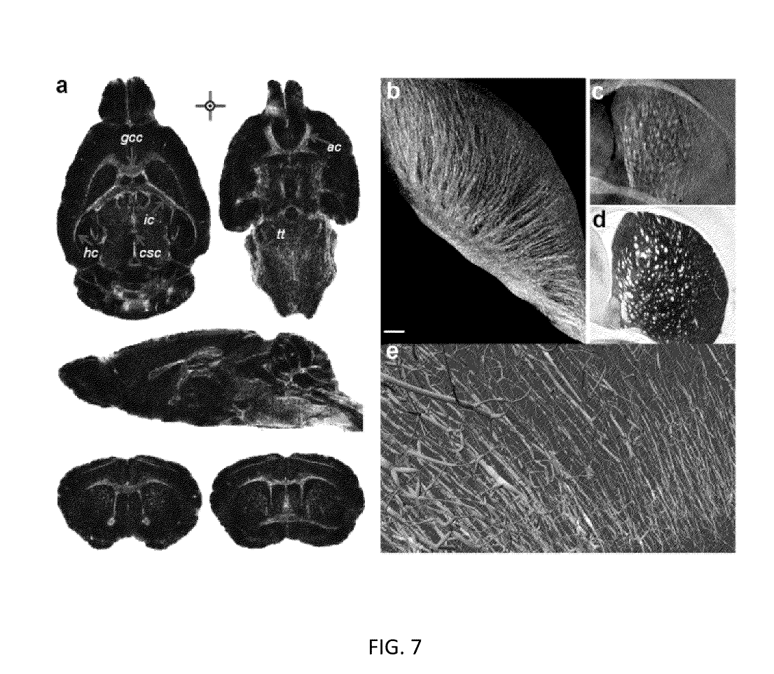

To illustrate the orientation of the minor eigenvector of the dipole susceptibility tensor χ_{d}, the orientations were color-coded with the intensity scaled by the trace of the tensor. The color scheme was: red representing left-right, green representing anterior-posterior and blue representing dorsal-ventral (FIG. 7(a)). The orientations were coherent within white matter fiber bundles, for example, the corpus callosum, the anterior commissure, the hippocampus, and the trigeminal tracts (FIG. 7(a)). The orientations also appeared to be consistent with the underlying axon orientation. For example, the genu corpus callosum appeared mainly red as it connects the right and left hemisphere. The laminated structure of the commissure of superior colliculus was clear visible, interconnecting the superior colliculi on either side. In the pons and the medulla, the trigeminal tract was mainly green as it runs anterior-posterior direction. The boundaries of the internal capsule had a shade of blue which was partly due to the interface between the white matter, the lateral ventricle and the striatum. At this resolution, multiple fibers existed within one voxel. The orientation maps of the minor eigenvectors were similar for χ_{d}, χ_{q} and η_{d} (FIG. 6(b)). The orientation map of η_{q}, on the other hand, was different and not indicative of fiber orientation. These findings were consistent with the simulation.

To evaluate the method at ultra-high resolution, 3D SPGR images of one brain were acquired at 10-μm resolution. A p-space reconstruction was performed at an isotropic 5-μm resolution by zeropadding the original k-space data for a region encompassing the right caudate putamen (striatum). One of the primary roles of the striatum is to integrate glutamatergic afferents that originate in the cortex and the thalamus. The main neuronal cell-type (>95%) and the principal projections neuron of the striatum is the medium-sized spiny neurons (MSN). The somata of the MSN have diameters ranging from 9 to 25 μm within the resolution of the acquired images. A maximum intensity projection (MIP) in the dorsal-ventral direction of the striatum highlighted the projections of the MSN clearly (FIG. 7(b)). Cross sections of these neurons were clearly identifiable in the coronal sections (FIG. 7(c)). The shapes and sizes of the neurons matched well with those from the histological slides stained with acetylcholinesterase (AChE). The neuronal tracks of the striatum have been constructed in 3D using the skeletonization tool in Avizo (VSG Inc. Burlington, Mass., USA) (FIG. 7(e)). The 3D topology provided clear visualization of the main tracks and braches due to striatal interneurons (arrows in FIGS. 7(c)-7(e)).

p-Space STI of Human Brain In Vivo

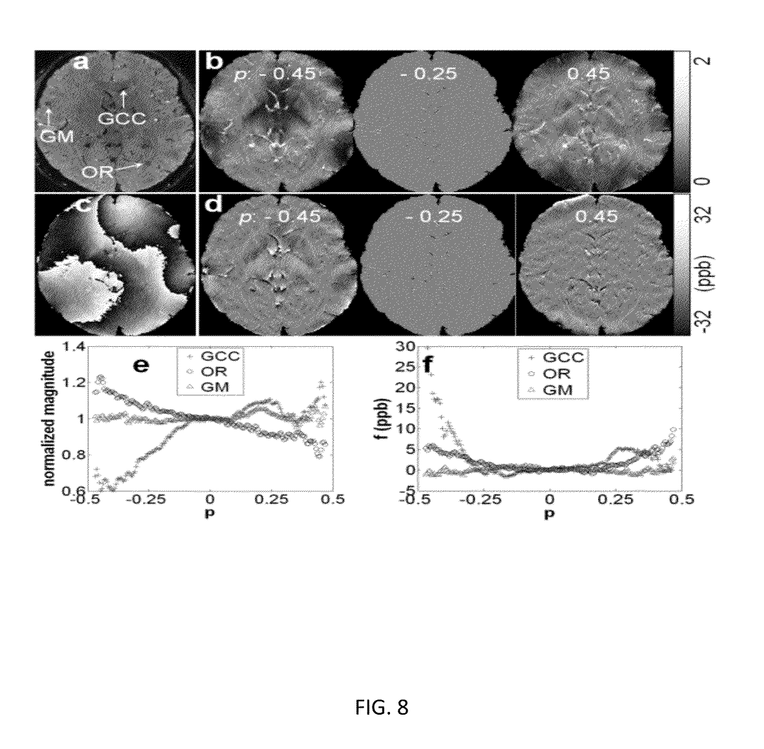

Imaging higher order susceptibility anisotropy in vivo under normal physiological condition is an important potential application of the p-space method. Although higher order information can be obtained by rotating the specimen, rotating a human head in a clinical MRI scanner is not convenient. To test whether the p-space method is capable of imaging anisotropic susceptibility tensors of human brains in vivo with standard clinical MRI scanners, 3D SPGR images were acquired on 3 healthy adult brains on a 3.0 Tesla GE MR750 scanner (GE Healthcare, Waukesha, Wis.). The resolution was 1.0-mm isotropic. Similar to the simulation and the mouse brains, the signal in the human brain white matter also varied significantly as a function of the p-value while the gray matter stayed relatively constant (FIG. 8).

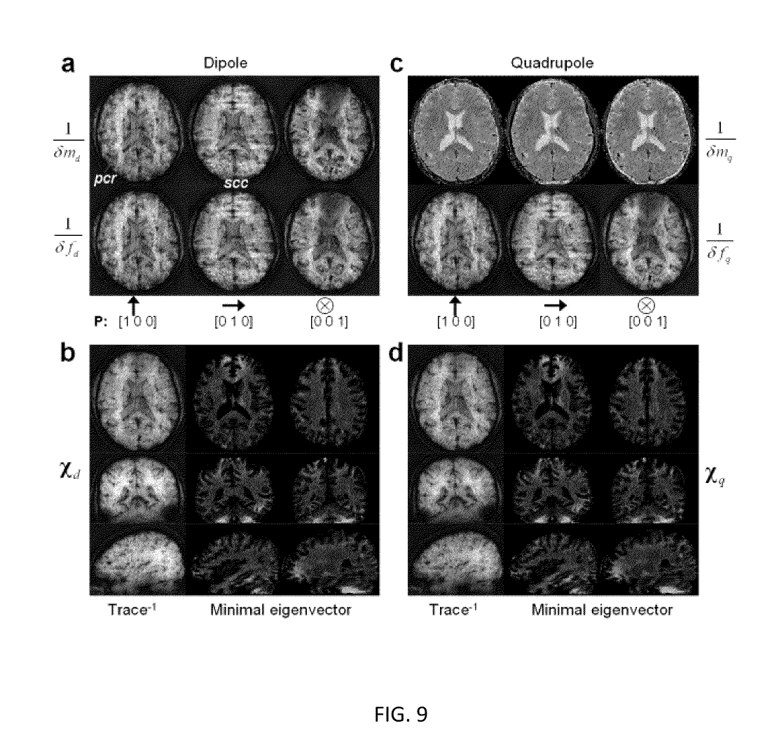

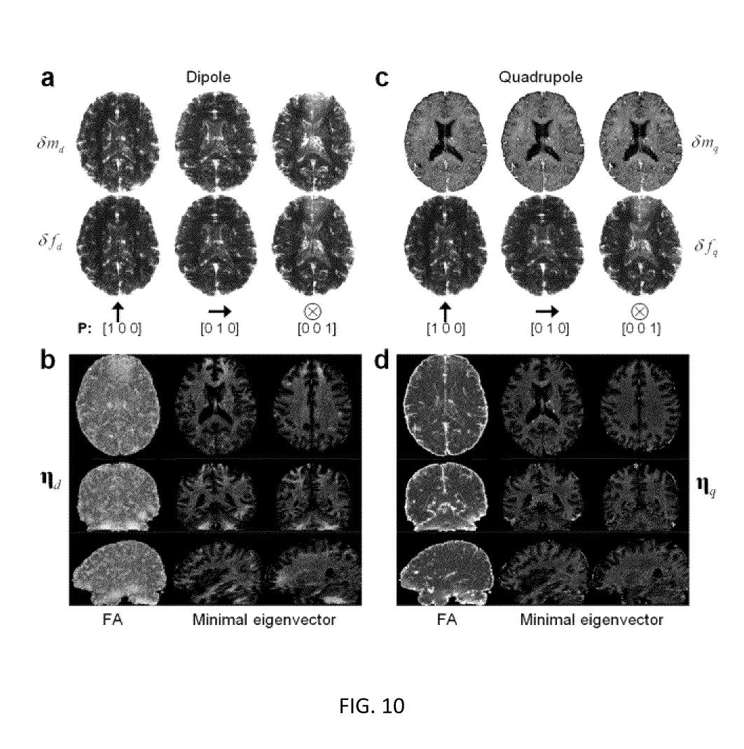

For the dipole terms, the inverse of the standard deviations (i.e. 1/δm_{d} and 1/δf_{d}) showed a clear dependence on the orientation of the p-vector (FIG. 9(a)). When the axons were parallel to the p-vector, both 1/δm_{d} and 1/δf_{d} were the largest in the corresponding white matter regions such as the posterior corona radiata (pcr) at p=[1 0 0] and the splenium of the corpus callosum (scc) at p=[0 1 0] (FIG. 9(a)). Conversely, when the axons were parallel to the p-vector, δm_{d} and δf_{d} were the smallest (FIG. 10). Based on this anisotropy, the dipole susceptibility tensors were computed (χ_{d} in FIG. 9(b) and η_{d} in FIG. 10). The orientation of the minor eigenvector was color-coded with red representing red-left, green representing anterior-posterior and blue representing superior-inferior (FIG. 9(b)). The color intensity was weighted by the product of the fractional anisotropy and the T1-weighted image. The color map demonstrated a clear heterogeneity of eigenvector orientations within white matter fiber bundles. For example, the body of the corpus callosum indicated a red-left direction (red) while the pcr indicated an anterior-posterior direction (green) confirming the anisotropy observed in the standard deviation map. The orientations were consistent between the two dipole tensors (FIG. 9(b) and FIG. 10(b)).

For the quadrupole terms, only the frequency demonstrated significant anisotropy (FIG. 9(c)). The magnitude showed weak anisotropy (FIG. 9(c)) but excellent tissue contrast which was consistent with the mouse brain experiments. Specifically, the contrast exhibited by 1/δm_{q} resembled that of a T2-weighted image (FIG. 9(c)). Quadrupole tensors were then computed for both the frequency (FIG. 9(d)) and the magnitude (FIG. 10(d)). For the frequency, the trace and the orientation of its minor eigenvector were similar to those of the dipole tensors (FIG. 9(d)). For the magnitude, the orientation of the minor quadrupole eigenvector differed completely from the dipole tensors. While the quadrupole tensor of the magnitude did not show any correlation with the fiber orientation, the quadrupole tensor of the frequency demonstrated a clear indication of underlying fiber structures. These findings were again consistent with the simulation and the ex vivo experiments.

### Separation of Background Fields

In some instances, it may be desirable to remove field and phase induced by sources outside the organ or region of interest. This phase may be wrapped around ±π. In accordance with embodiments, a method may simultaneously performs phase unwrapping and harmonic (background) phase removal using the Laplacian operator (HARPERELLA). The Laplacian of the phase can be derived from the sine and cosine functions of the wrapped phase directly with the following:

∇²φ=cos φ ²∇ sin φ sin φ ²∇ cos φ [15]

The relationship between the Laplacian of the phase image and the underlying magnetic susceptibility distribution is given by:

∇²φ=γ T·E μ₀H₀(²∇χ/3−²∂χ/z∂²) [16]

Eq. [16] is a Poisson equation, in which the local elements of (∇²/3−∂²/∂z²)χ can be regarded as sources that generate the tissue phase obeying the principle of superposition. Solving Eq. [15] yields the unwrapped phase that is free of contributions from sources outside the FOV, while Eq. [16] gives the susceptibility maps.

If the phase measurement is available everywhere within the whole imaging FOV including areas without tissue support, then both equations can be solved in the spatial frequency domain by assuming periodic boundary conditions at the edges of the FOV. This approach is fast as it takes advantage of the Fast Fourier Transform (FFT) algorithm. Specifically, the Laplacian of the sine and cosine can be calculated using Fourier transforms:

∇² sin φ=4π²FT⁻¹[k²FT(sin φ)] [17]

∇² cos φ=4π²FT⁻¹[k²FT(cos φ)] [18]

Unfortunately, phase measurements are typically not available outside the tissue. Therefore, generally, Eq. [15] and [16] must be solved with boundary conditions set at the irregularly shaped tissue boundaries and the FFT algorithms can no longer be applied. In addition, although the boundary conditions are governed by Maxwell's equations in principle, it is difficult to define them rigorously as only the z-component of B-field is measurable by MRI. Even if the boundary conditions were defined properly, solving the partial differential equations would still be computationally intensive.

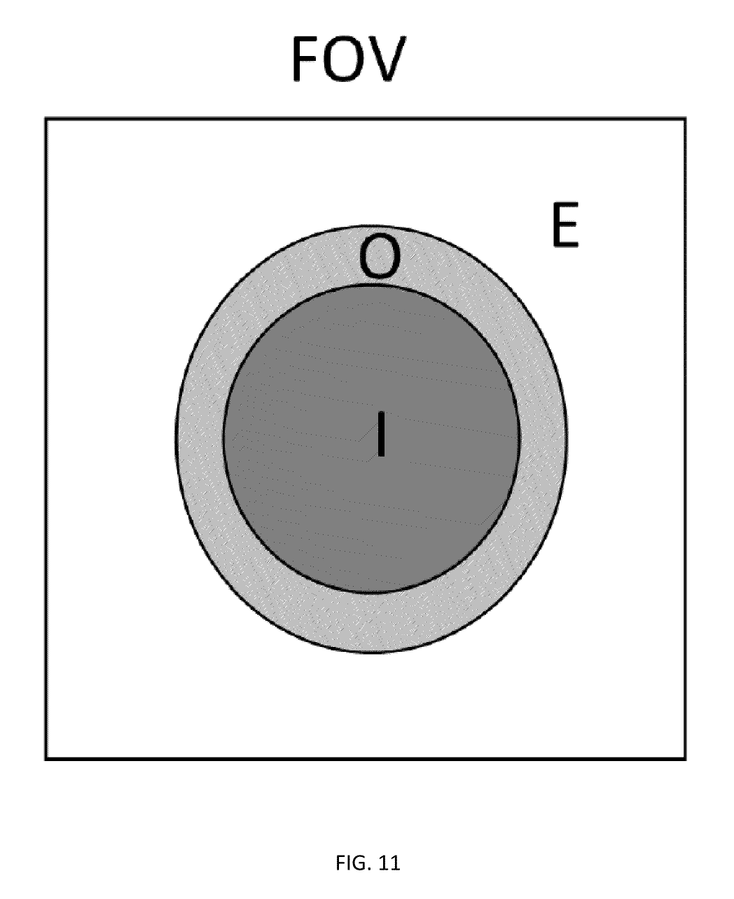

To take advantage of the simplicity of the Fourier approach and the FFT algorithm, the phase outside the tissue has to be determined. Let I and O be the interior and boundary regions of the tissue respectively, and E is the relative complement of I and O with respect to the FOV, i.e. I ∪ O ∪ E=FOV (FIG. 11). Region O is the set of tissue voxels next to the boundaries that are within a distance of the radius of the spherical mean value filter. Then the phase Laplacian within the region of E, ∇²φ_{E}, shall be the solution of the following minimization problem:

$${min}_{{∇}^{2} {ϕ}_{E}} {‖ S ( {∇}^{2} {ϕ}_{E} ) + S ( {∇}^{2} {ϕ}_{I + O} ) - δ ‖}_{2} \qquad [ 19 ]$$

where “S” represents the spherical mean value operator over a sphere centered around a given spatial location, and the residual susceptibility sources δ are estimated as the mean over trustable region I

δ=[ S̅(̅²̅φ̅)̅∇]_{I} [20]

The reasons why φ_{E} has to minimize the spherical mean value of the Laplacian according to the above equation are two-fold: first, the Laplacian of the phase removes all contributions from sources outside the FOV; second, the sum of all MRI-measurable susceptibility sources shall be very close to zero within the FOV as RF carrier frequency is typically tuned to the mean frequency; and finally, any residual susceptibility sources are considered using δ.

Once φ_{E} is determined, the Laplacian for the whole FOV, ∇²®_{FOV}, can be determined as

∇²φ_{FOV}=∇²φ_{I+O}+∇²φ_{E} [21]

Finally, the background removed and unwrapped phase can be obtained using the following FFT-based inverse Laplacian:

φ=F∇T⁻¹[FT(²φ_{FOV})/4π²k²] [22]

For convenience, reference is made to this method as HARmonic PhasE REmoval with LapLAcian, or HARPERELLA in short. It is emphasized that HARPERELLA achieves both phase unwrapping and background phase removal in a single integrated procedure purely based on the Laplacian operator.

### HARPERELLA

A 3D 128×128×128 Shepp-Logan phantom was used to evaluate the accuracy of HARPERELLA. The phantom was zero padded to 384×384×384 for accurate simulation of the corresponding resonance frequency map. The phantom was composed of multiple ellipsoids placed in a homogenous background with zero susceptibility. The susceptibility values for the ellipsoids were 0, 0.2 and 0.3 ppm, respectively. A cubic object of 100 ppm was placed outside the multiple ellipsoids and served as the external source generating the background field. The background phase was removed using HARPERELLA and compared with the ground truth.

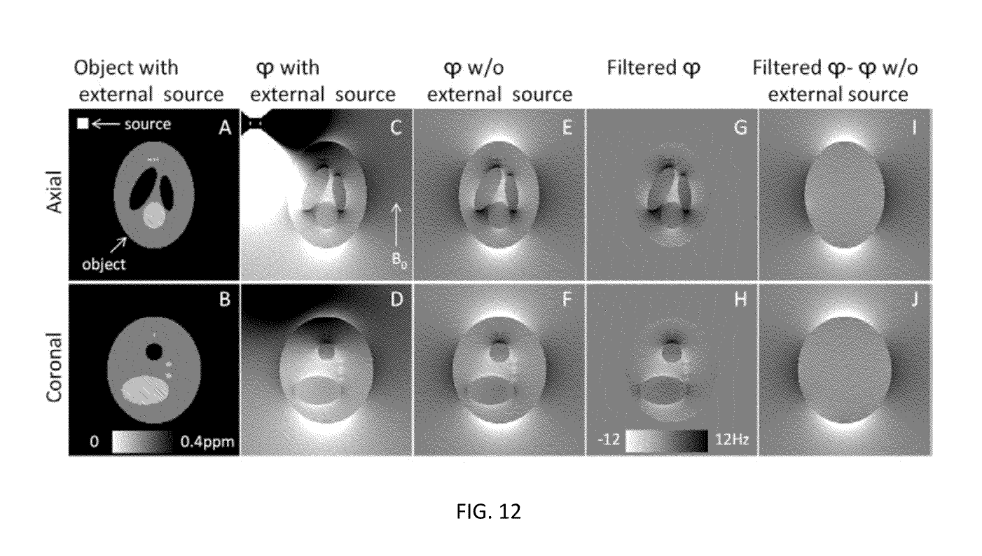

FIG. 12 shows the accuracy of the HARPERELLA for background phase removal. Compared to the phase images generated in the absence of the external source (FIGS. 12E and F), a very strong background phase inside the ellipsoids can be observed when the external source is included in the simulation (FIGS. 12C and D). The HARPERELLA methods effectively removed the background phase (FIGS. 2G and H). The difference between the HARPERELLA filtered phase and the phase generated by the object in the absence of the external source does not contain contrast of the internal ellipsoids, indicating the accuracy of HARPERELLA in preserving the phase contrast of internal structures.

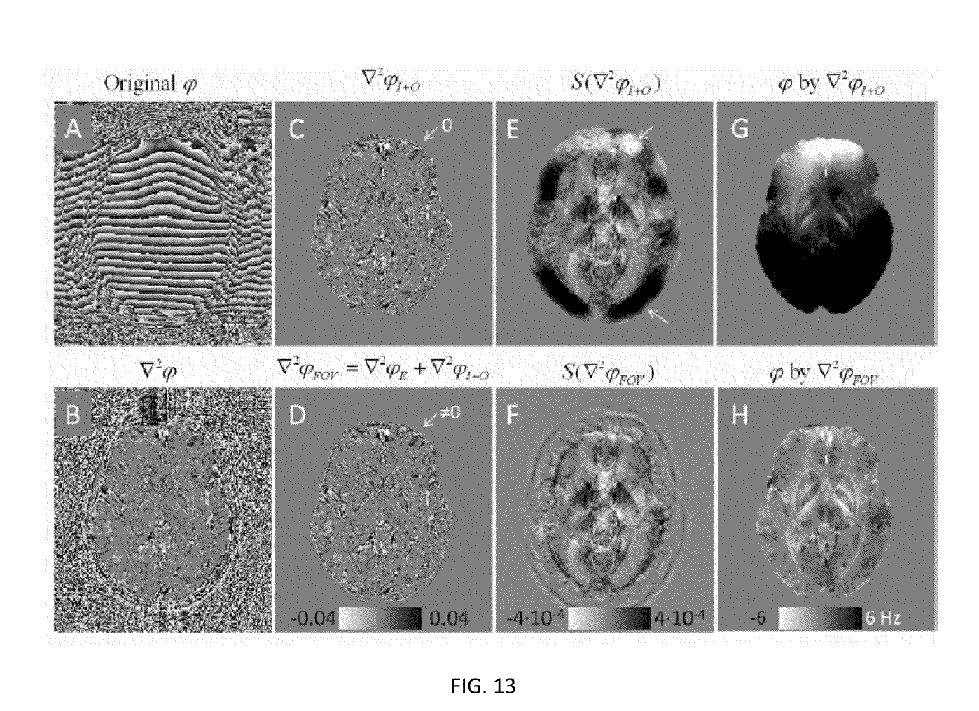

FIG. 13 illustrates the procedures and underlying principles of HARPERELLA. The phase Laplacian (FIG. 13B) calculated from the original phase (FIG. 13A) is inaccurate outside the brain. If the Laplacian outside the brain is simply masked out (FIG. 13C), the unwrapped phase calculated using Eq. 21 still contains a significant contribution of background phase (FIG. 3G). This can be understood using the spherical mean values of the Laplacian (FIG. 13E). The Laplacian of the brain tissue mainly contains edges that are the “sources” of phase contrast. Inside the brain, the “positive sources” cancel the adjacent “negative sources”, so that the magnitude of the spherical mean value of the phase Laplacian is two orders of magnitude smaller than that of the phase Laplacian values at the boundary of the brain. The inaccurate Laplacian values at the brain boundary give rise to net “positive” or net “negative” sources, which can be easily seen in the spherical mean value maps (FIG. 13E, arrows). It is these net “positive” or net “negative” sources that give rise to the background phase in FIG. 13G.

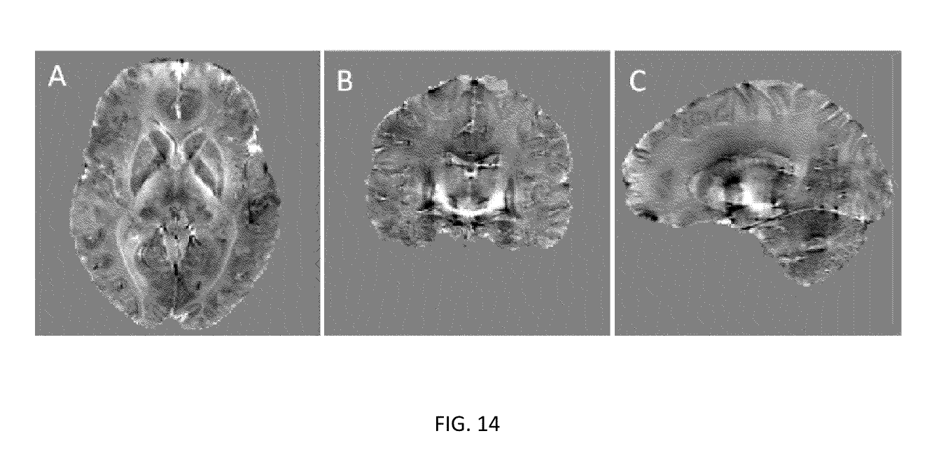

With HARPERELLA, the Laplacian values of the brain tissue are intact. The Laplacian values outside the brain are estimated (FIG. 13D), so that the spherical mean values is uniform throughout the FOV (FIG. 13F). More intuitively, the “positive sources” always cancel the adjacent “negative sources,” so that there is no net background source throughout the FOV. Correspondingly, the background phase contribution is effectively removed in the unwrapped phase image (FIG. 13H) using Eq. 21. A view of the HARPERELLA processed phase in 3D is shown in FIG. 14.

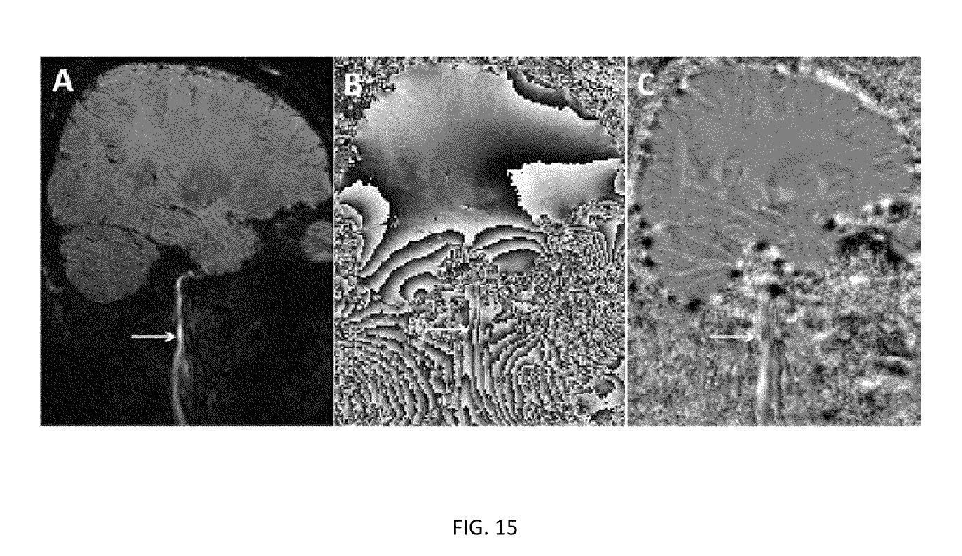

The use of the Fast Fourier Transform ensures efficiency, while the use of sine and cosine functions to calculate the Laplacian provides the robustness that allows reliable continuous phase unwrapping even in noisy voxels around blood vessels (FIG. 15).

### Example Applications

Despite the paramount importance of frequency shift has attained in NMR, the impact of frequency shift in MRI has been very limited. While measuring frequency shift and its anisotropy has enabled NMR to determine structures of large molecules, MRI has not been able to utilize the vast information existed in the frequency. Yet, the similarity between the frequency shift caused by the atomic arrangement in a large molecule and that by an ordered tissue microstructure cannot be overlooked. The p-space STI method developed here provides MRI a means to measure this higher order frequency information and utilize it to elucidate tissue microstructure. The method is fast, requiring only a single acquisition of 3D gradient-recalled-echo images. It also allows high spatial resolution as demonstrated by the 10-μm imaging of the spiny neurons in the mouse striatum. A key innovation of the method is the ability to image anisotropic susceptibility tensors in vivo without rotating the object or the magnetic field. Although the method was demonstrated here using proton MRI as an example, the present subject matter is also applicable for other non-proton nuclei. The p-space method is expected to open a new avenue for studying tissue microstructure in general and brain connectivity in particular.

The ability to quantify anisotropic tissue property based on a single image acquisition was made possible by sampling and analyzing the p-space signal of each voxel. The p-space can be sampled by applying a pulsed field gradient prior to data acquisition, or equivalently, by shifting the acquired k-space data by a desired p-vector. To maintain overall signal consistency, the central k-space signal (the DC signal) should not be shifted outside the reconstruction window. As a result, the p-value applied along any direction should be smaller than 0.5. On the other hand, the more orientations are sampled in the p-space, the more accurate the susceptibility tensors can be estimated. The gain in signal-to-noise ratio (SNR), however, does not increase proportionally with the number of orientations. This behavior is caused by the correlated noise among p-space images that are reconstructed from the same raw data. In this demonstration, 213 orientations were used, which resulted in a good tradeoff between computational efficiency and SNR.

Analyzing the signal variations among these directions allowed us to determine a set of dipole (χ_{d} & η_{d}) and quadrupole (χ_{q} & η_{q}) susceptibility tensors. These four tensors characterize the anisotropic signal behavior in the p-space while the conventional susceptibility tensor χ characterizes frequency shift in the image space. The anisotropy of the conventional susceptibility tensor χ describes the differential magnetization induced by external magnetic fields of different orientations. Measuring this anisotropy requires a rotation of the external field with respect to the object which has limited the practicality of previous STI implementation. In contrast to the conventional susceptibility tensor, the p-space tensors describe the signal heterogeneity within one voxel at a given external field orientation. By expanding the p-space signal with the Taylor's series, higher-rank magnetic multipole tensors were projected onto the direction of the external field thus reducing the anisotropy to a 3D space. Although the anisotropy with rank-2 tensors was shown here an example, the method can be readily extended to include tensors of higher ranks In fact, higher rank may be necessary to characterize more complex tissue structures. The p-space anisotropy may also be characterized in the spherical coordinate where the anisotropy can be described by a set of spherical harmonics.

The present subject matter developed a practical method for imaging anisotropic susceptibility tensors. Although these tensors were estimated based on the standard deviations, other numerical methods may also be used based on the p-space methodology. In the simple case of parallel axons, the minor eigenvectors of three susceptibility tensors were identified and aligned with the axons. In the complex structure of spiny neurons in the striatum, the skeletoniztaion approach was utilized. Application of tensor-based tracking algorithms and software can also be utilized. Sophisticated algorithms can be used to take advantage of the unique properties of these susceptibility tensors and ultra-high spatial resolution.

The p-space approach provides a general method for analyzing electromagnetic field distribution on voxel and subvoxel levels. For example, p-space analysis may be applied to recover signal losses due to intravoxel dephasing, resulting in a post-acquisition “shimming” effect. This analysis can be used to improve the computation of the image domain susceptibility. The analysis of field distribution can also be used to correct image artifacts caused by field inhomogeneity, e.g. image blurring in non-Cartesian imaging and geometric distortion in echo-planar imaging. As a demonstration, it has been assumed that the p-space signal behaves linearly as a function of TE. The method does not exclude nonlinear effect. It is anticipated that the existence of nonlinearity which can be readily incorporated into the method. While p-values up to ±0.5 were used in the examples for demonstration purposes, the method also encompasses the use of p-values outside that particular range. Larger p-values provide higher sensitivity.

For the purpose of illustration, the method was shown with analyses performed in the frequency domain. The method can be equally applied in the image domain given the well known relationship between image space and frequency space.

With the p-space method, probing brain microstructure in vivo at resolutions higher than what current MRI methods are capable of may become possible. Higher field strength will further extend the ability of the method to quantify susceptibility anisotropy. At higher field, each spin accrues more phase offsets thus increasing the signal range along any given orientation and improving our ability to quantify the variations between different orientations. Exploring the capability of the p-space method for imaging neuronal and muscular fiber connectivity may be of great interest for applications in which diffusion tensor imaging reaches its limits, such as imaging at high spatial resolution and at ultra-high field strength when tissue heating becomes problematic. The method can be applied to image a variety of tissue changes at diseased states for purposes such as diagnosis, prognosis, treatment and surgical planning, and the like. p-space STI may also be implemented to study moving organs such as kidneys, livers, fetus brains and even beating hearts. The method can also be used to detect measure and image electromagnetic fields induced by bioelectrical currents such as those by neuronal activities. Such bioelectrical currents will induce a perturbation of subvoxel electromagnetic fields.

The various techniques described herein may be implemented with hardware or software or, where appropriate, with a combination of both. Thus, the methods and apparatus of the disclosed embodiments, or certain aspects or portions thereof, may take the form of program code (i.e., instructions) embodied in tangible media, such as floppy diskettes, CD-ROMs, hard drives, or any other machine-readable storage medium, wherein, when the program code is loaded into and executed by a machine, such as a computer, the machine becomes an apparatus for practicing the presently disclosed subject matter. In the case of program code execution on programmable computers, the computer will generally include a processor, a storage medium readable by the processor (including volatile and non-volatile memory and/or storage elements), at least one input device and at least one output device. One or more programs may be implemented in a high level procedural or object oriented programming language to communicate with a computer system. However, the program(s) can be implemented in assembly or machine language, if desired. In any case, the language may be a compiled or interpreted language, and combined with hardware implementations.

The described methods and apparatus may also be embodied in the form of program code that is transmitted over some transmission medium, such as over electrical wiring or cabling, through fiber optics, or via any other form of transmission, wherein, when the program code is received and loaded into and executed by a machine, such as an EPROM, a gate array, a programmable logic device (PLD), a client computer, a video recorder or the like, the machine becomes an apparatus for practicing the presently disclosed subject matter. When implemented on a general-purpose processor, the program code combines with the processor to provide a unique apparatus that operates to perform the processing of the presently disclosed subject matter.

Features from one embodiment or aspect may be combined with features from any other embodiment or aspect in any appropriate combination. For example, any individual or collective features of method aspects or embodiments may be applied to apparatus, system, product, or component aspects of embodiments and vice versa.

While the embodiments have been described in connection with the various embodiments of the various figures, it is to be understood that other similar embodiments may be used or modifications and additions may be made to the described embodiment for performing the same function without deviating therefrom. Therefore, the disclosed embodiments should not be limited to any single embodiment, but rather should be construed in breadth and scope in accordance with the appended claims.

The patent or application file contains at least one drawings executed in color. Copies of this patent or patent application publication with color drawing(s) will be provided by the Office upon request and payment of the necessary fee.

What is claimed:

1. A method for susceptibility tensor imaging in the p-space, the method comprising:
using a magnetic resonance imaging (MRI) system to generate an MRI signal of an object; and
measuring subvoxel electromagnetic fields in a spectral space (p-space).

2. The method of claim 1, wherein using the MRI system comprises using the MRI system to apply an electromagnetic field to the object.

3. The method of claim 1, wherein using the MRI system comprises using the MRI system to continuously acquire image data of the object.

4. The method of claim 1, wherein measuring the subvoxel electromagnetic field comprises sampling the p-space with pulsed field gradients to determine a set of dipole and quadrupole susceptibility tensors.

5. The method of claim 1, wherein measuring the subvoxel electromagnetic field comprises generating a plurality of images of the object based on a set of dipole, quadrupole, and higher order tensors for depicting a characteristic of the object.

6. The method of claim 1, further comprising constructing the p-space in both real and frequency domain.

7. The method of claim 1, wherein the electromagnetic field have an origin of one of electric and magnetic.

8. The method of claim 1, wherein using the MRI system comprises using the MRI system to acquire the image echoes by one of spin wrap, interleaved spiral, partial and segmented echo planar imaging (EPI) trajectories.

9. The method of claim 1, wherein using the MRI system comprises using the MRI system to acquire each image echo by a segmented three-dimensional echo planar imaging (EPI) trajectory.

10. The method of claim 1, wherein generating MRI signal comprises generating one of a single echo and multiple echoes of signals.

11. The method of claim 1, wherein the MRI signal comprises a signal generated by an MRI sequence with magnetization preparation.

12. The method of claim 1, further comprising implementing in p-space for characterizing NMR and MRI signals.

13. The method of claim 1, further comprising quantifying p-space signal with a set of basis functions.

14. The method of claim 1, further comprising using a p-space signal to characterizing microstructures, properties, activities, and functions of the object.

15. The method of claim 1, further comprising reconstructing object orientations, orientation distribution functions, and connectivity based on electromagnetic fields.

16. A magnetic resonance imaging (MRI) system comprising:
an MRI device configured to generate an MRI signal of an object; and
an image generator configured to:
conduct a multipole analysis of the MRI signal in a subvoxel Fourier spectral space (p-space);
sample the p-space with pulsed field gradients to determine a set of dipole and quadrupole susceptibility tensors; and
generate an image of the object based on the set of dipole and quadrupole susceptibility tensors for depicting a characteristic of the object.

17. The MRI system of claim 16, wherein the MRI device is configured to apply a magnetic field to the object.

18. The MRI system of claim 16, wherein the MRI device is configured to continuously acquire image data of the object.

19. The MRI system of claim 16, wherein the MRI device is configured to acquire the image echoes by one of spin wrap, interleaved spiral, and segmented echo planar imaging (EPI) trajectories.

20. The MRI system of claim 16, wherein the MRI device is configured to acquire each image echo by a segmented three-dimensional echo planar imaging (EPI) trajectory.

21. A method of separating of background electromagnetic fields from those generated by objects within a region of interest by solving the Laplacian equation with boundary conditions.

22. The method of claim 21, further comprising partitioning the image space into regions to compute the Laplacians.
